(19) United States
(12) Patent Application Publication
(10) Pub. No.: US 2026/0349516 A1
(43) Pub. Date: Nov. 5, 2026

(54) FLEXIBLE HAPTIC INTERFACE, METHOD FOR GENERATING A HAPTIC EFFECT, AND METHOD FOR MANUFACTURING THE FLEXIBLE HAPTIC INTERFACE

(71) Applicant: COMMISSARIAT A L'ENERGIE ATOMIQUE ET AUX ENERGIES ALTERNATIVES, Paris (FR)

(72) Inventor: Romain LE MAGUERESSE, Grenoble (FR)

(21) Appl. No.: 19/487,491

(22) PCT Filed: Jun. 14, 2024
(86) PCT No.: PCT/EP2024/066698

§ 371 Date: Nov. 25, 2025

(30) Foreign Application Priority Data
Jun. 16, 2023 (FR) FR2306217

(51) Int. Cl. G06F 3/01; B06B 1/06; H10N 30/073; H10N 30/88

(52) U.S. Cl. CPC G06F 3/016; B06B 1/0629; H10N 30/073; H10N 30/88

(57) ABSTRACT

A flexible haptic interface defining a touch surface (S) capable of being touched by a user, the interface including: —a plurality of rigid tactile elements joined by a flexible carrier; and —in contact with each rigid tactile element, at least one actuator, the actuators being arranged to transmit a mechanical excitation to the rigid tactile elements in order to drive the flexible carrier in contact with the rigid tactile elements to vibrate with a tactilely detectable flexible-carrier vibration amplitude (f), the ratio e/L of the thickness e of the flexible carrier to the spacing L between at least two adjacent tactile elements being less than or equal to 0.02.

### TECHNICAL FIELD

The present invention relates to human-machine interfaces, and more specifically to those producing haptic effects, notably multi-point haptic effects.

### PRIOR ART

A haptic interface allows the user to interact with the environment by the sense of touch. The haptic effect is currently increasingly used in numerous applications, for example, on a “smartphone”, when said smartphone generates a slight vibration when a key displayed on the screen is pressed in order to simulate the impression of pressing a button. Haptic applications also exist for virtual or augmented reality devices, in particular to allow better immersion in video games. Haptic interfaces such as tactile pads, generating a haptic effect on a touch surface when contacted by a user, notably can be integrated into numerous technologies such as computers, tablets and/or smartphones.

Generating diverse and relatively complex haptic effects on a rigid touch surface is known by means of ultrasonic transducers emitting ultrasonic waves that propagate on the rigid surface.

With the emergence of flexible commercial products on the market, such as foldable mobile telephones or even rollable televisions, it is worthwhile having flexible haptic interfaces that can be integrated into such products.

The use of a simple flexible support supporting ultrasonic transducers is nevertheless limited because the waves emitted by the transducers are partly absorbed by the flexible material; the haptic effect that is generated is then hardly perceptible by a user applying pressure on such a support with their finger or their hand.

The use of pneumatic actuation is also known for generating haptic effects on a flexible structure. U.S. Pat. No. 10,240,688 B2 discloses a flexible haptic interface comprising pneumatic actuators allowing a topology effect to be generated.

The article by Yu et al., entitled, “Skin-integrated wireless haptic interfaces for virtual and augmented reality”, (Nature, 2019), discloses a flexible haptic interface comprising magnetic actuators allowing diverse haptic effects to be generated. However, the spatial resolution of the haptic effects that are obtained with such an interface is relatively low, and the use of magnetic actuators results in high electrical consumption.

Finally, non-Newtonian fluids have already been used in order to generate simple haptic effects, such as button effects and relief effects. The article by Lochtefeld entitled, “Towards real organic user interfaces-using non-Newtonian fluids for self-actuated displays”, (CHI13 workshop, 2013), describes a haptic device using a shear-thickening non-Newtonian fluid taken between two flexible sheets installed on a fixed array of loudspeakers. A topology perceptible to the finger is generated when a sound wave propagates in the fluid and hardens it locally.

Moreover, a multi-point haptic device allows simultaneous and multiple points of contact to be recognized. It generally comprises a haptic interface as well as software that interprets the simultaneous contacts. In order to be effective enough, the multi-point haptic devices need the haptic effects on the haptic interface to be properly located, for example, via localized friction modulation.

Patent FR 3064504 describes a non-flexible and non-conformable interface offering localized friction modulation.

Applications FR 3124617 and FR 3125144 describe non-flexible and non-conformable tactile simulation interfaces comprising acoustic wave containment zones delimited by acoustic mirrors produced by acoustic metamaterials. These applications do not describe multi-point haptic interfaces.

Application US 2012/293441 describes non-flexible tactile interfaces.

Application FR 31128546 describes haptic interfaces with flexible hinges.

Application US 2017/005077 describes a flexible device, comprising electrical components comprising vibrators to provide haptic feedback and tactile sensors, with the components being mounted on a flexible substrate.

Application EP 3401763 describes a computing device comprising a touch surface comprising tactile sensors, with the device further comprising several haptic output devices.

Application US 2012/229401 describes a haptic user interface comprising a flexible surface layer and a haptic substrate, with the surface layer comprising, for example, several regions each able to accept a tactile input, and the substrate comprising several actuators.

Application US 2017/068318 describes a device comprising a foldable screen, a foldable housing, and input-output devices, notably comprising tactile sensors and a haptic output device.

### DISCLOSURE OF THE INVENTION

A requirement exists for improving flexible haptic interfaces, notably in order to provide a tactile interface, which is preferably conformable, capable of generating diverse haptic effects, exhibiting good spatial resolution over the entire interface, and allowing properly located multi-point haptic effects to be generated.

### SUMMARY OF THE INVENTION

The invention aims to address this requirement, and achieves this aim, according to a first aspect thereof, by virtue of a flexible haptic interface defining a touch surface able to be touched by at least one user, the interface comprising:
a plurality of rigid tactile elements connected by a flexible support; and
at least one actuator, superimposed on each rigid tactile element, with the actuators being arranged to transfer mechanical excitation to the rigid tactile elements in order to vibrate the flexible support,
   with the ratio e/L of the thickness e of the flexible support to the spacing L between at least two adjacent tactile elements being less than or equal to 0.02.

The term “tactilely detectable” is understood to mean that the vibration amplitude of the hinge typically exceeds an amplitude of 1 micron under a load ranging between 0.05 and 0.5 N.

The term “transferring mechanical excitation to the elements” is understood to mean inducing a vibration of the elements with a tactilely detectable amplitude, with the vibration amplitude of the rigid tactile elements being able to be different from that of the flexible support, notably lower.

By virtue of the invention, haptic effects can be obtained that exhibit satisfactory spatial resolution, since the vibration of the flexible support contributes, in addition to that of the excited rigid tactile elements, to the haptic effect generated by the haptic interface.

Localized haptic effects also can be obtained that allow the haptic interface to be used to create multi-point haptic effects, for example.

This can be achieved when some actuators of the interface are electrically powered, while other actuators of the interface are not electrically powered. Notably by virtue of the ratio e/L defined above, the rigid tactile elements in contact with the non-powered actuators act as acoustic mirrors and/or waveguides and can reflect the acoustic waves emitted by the rigid tactile elements propagating in the flexible support.

These reflected acoustic waves can interact with the incident acoustic waves in any constructive interference, increasing the amplitude of the acoustic waves in the vicinity of the active rigid tactile elements, i.e., excited by corresponding electrically powered actuators. Furthermore, since the acoustic waves are reflected by the passive rigid tactile elements, i.e., in contact with non-electrically powered actuators, the vibration amplitude in the vicinity of these elements remains limited; this allows any vibrations in the vicinity of the active rigid tactile elements to be properly localized. Due to these localized haptic effects, it is possible to obtain good quality multi-point haptic effects.

Thus, a haptic interface is provided with a certain degree of flexibility, pliability and conformability, while offering diverse and localized haptic effects with good spatial resolution.

The term “conformable haptic interface” is understood to mean a haptic interface that can be adapted on a non-flat support, and that is capable of substantially matching the shape.

Preferably, the interface comprises a control circuit configured to modulate the signals sent to the actuators in order to mechanically induce the vibration of the elements and of the flexible support and to generate a haptic sensation on the touch surface. The control circuit is preferably configured so as to allow the modulation of each actuator to be individually controlled. The control circuit can control the voltage of the signal, the frequency of the signal, the phase of the signal and/or the ultrasonic frequency of each actuator individually. It can thus comprise an array of electronic switches for selectively activating each of the actuators, according to the desired excitation pattern.

The vibration of the elements and of the flexible support can generate a variation in friction that is tactilely perceptible by a user moving their finger over the touch surface. This effect, also called the “squeeze-film” effect, can give the user the impression of touching a surface with reliefs, or with different textures.

The vibration of the elements and of the flexible support can also generate a pulse that is tactilely perceptible by a user exerting a static contact on the touch surface. This effect gives, for example, the user the impression of pressing a button.

### Rigid Tactile Elements

The invention is not limited to the excitation of individual tactile elements of a particular material, or with a particular shape. However, certain shapes and certain materials can facilitate the manufacture of the interface.

Thus, at least some of the rigid tactile elements, better still all the rigid tactile elements, can assume a general polyhedral shape, preferably a parallelepiped shape. The rigid tactile elements notably can be in the form of rectangular, in particular square, strips, as a front view. As a variant, the rigid tactile elements can be in the form of circular strips.

At least some of the rigid tactile elements, better still all the rigid tactile elements, are preferably made of a relatively rigid, hard and/or common material, such as glass, preferably borosilicate glass, silicon, a metal, for example, aluminum, copper or stainless steel, or a hard polymer, notably a polymer with a Young's modulus that is greater than the Young's modulus of the flexible support, for example, greater than 10 GPa.

At least two rigid tactile elements can have rigid supports that are different from each other.

At least some of the rigid tactile elements, better still all the rigid tactile elements, preferably have a substantially constant thickness, preferably ranging between 50 microns and 5 mm, better still between 200 and 700 microns.

At least some of the rigid tactile elements, better still all the rigid tactile elements, can have a surface area of at least 1 cm², for example, a surface area with dimensions of at least 10 mm by at least 15 mm, when the elements assume the shape of a rectangular strip as a front view.

All the rigid tactile elements can be identical. As a variant, individual rigid tactile elements with different sizes can be combined within the same interface, as a function, for example, of their location relative to the touch surface and/or of the application.

### Flexible Support

The term “support” denotes any single- or multi-layer structure that allows the rigid tactile elements to be retained in position, and allows their cohesion within the haptic interface. The flexible support is preferably formed by one or more polymeric materials, which can facilitate the manufacture and the acquisition of the desired flexibility for the haptic interface, while generating a deformation with the desired amplitude.

The flexible support can comprise polycarbonate (PC), polyethylene terephthalate (PET), polyethylene naphthalate (PEN), polyetheretherketone (PEEK), KAPTON, a green polymer, or any other suitable material.

The thickness of the flexible support can be selected as a function of the flexibility thereof, the softer the flexible support, the greater its thickness, while allowing the desired flexibility to be preserved.

Preferably, the flexible support has a substantially constant thickness, with the thickness preferably ranging between 25 and 200 microns. This low thickness allows good propagation of the vibrations on the surface of the flexible support.

The flexible support can have an equivalent Young's modulus that is greater than or equal to 1.5 GPa, notably less than or equal to 10 GPa.

The term “equivalent Young's modulus” is understood to mean, for a multi-layer flexible support, the average of the Young's moduli of the various layers weighted by the thicknesses of said layers.

The rigid tactile elements are advantageously made of a material that is more rigid than that or those of the flexible support. The ratio of the Young's modulus of each rigid tactile element to that of the flexible support is, for example, greater than or equal to 8, better still greater than or equal to 20, even better still greater than or equal to 50, more preferably ranging between 80 and 90, notably equal to approximately 85.

The rigid tactile elements can be integrated into the flexible support in various ways, depending on the structure of the flexible support.

The flexible support can be made up of one or more layers.

The flexible support notably can comprise a support layer and a layer for compensating for the thickness of the elements. This compensation layer can extend between the rigid tactile elements, above the support layer.

The compensation layer and the support layer form, when they are connected together at their interface between two adjacent rigid tactile elements, multi-layer hinges, notably bilayer hinges, between these elements.

The support layer can also act as a protective layer for the rigid tactile elements and/or the actuators provided thereon.

Preferably, the flexible support or, in the case of a support layer and a compensation layer, the support layer has a substantially constant thickness, preferably ranging between 50 nm and 500 microns, better still between 25 and 100 microns, for example, 75 μm.

The support layer by itself can retain the rigid tactile elements within the haptic structure. The thickness compensation layer can also fulfil this role, in conjunction with the support layer.

The rigid tactile elements may all be located on the same side of the support or of the support layer.

When present, the compensation layer preferably has a substantially constant thickness, preferably ranging between 25 microns and 300 microns, preferably between 25 and 100 microns, for example, 75 microns.

The flexible support can continuously extend over the entire extent of the touch surface, with the rigid elements being covered by the support, with the support preferably having a constant thickness.

As a variant, at least some of the rigid tactile elements, preferably all the rigid tactile elements, can have an outer surface opening onto the touch surface. This outer surface of the rigid tactile elements can be flush with the outer surface of the compensation layer, with the outer surface of the elements and that of the compensation layer then defining a substantially smooth surface that can act as a touch surface for the interface.

The user then comes into direct contact with the rigid tactile elements when they bring their finger into contact with the touch surface.

As a further variant, the rigid tactile elements and the compensation layer can be covered with a protective layer, which may or may not be identical to the support layer of the flexible support. It is thus possible to obtain a flexible support comprising three layers between the rigid tactile elements, when the vibration of the protective layer is mechanically coupled with that of the underlying layers. The thickness of the protective layer is preferably relatively small, so as not to further affect the feeling of the tactile effect in the vicinity of the rigid tactile elements.

The flexible support can comprise housings, into which the rigid tactile elements at least partially extend, with the rigid tactile elements being continuously covered, for example, by a flexible sheet defining the touch surface.

In one embodiment, the support comprises a layer for receiving the tactile elements, with the reception layer forming housings in the form of a bowl, with the support also comprising a layer for covering the elements, defined, for example, by the aforementioned flexible sheet.

The cover layer notably allows the touch surface to be rendered externally uniform, and prevents any parasitic tactile sensations that might otherwise occur if the user was in direct contact with the rigid tactile elements and/or neighboring regions, which can form a heterogeneous surface to the touch.

The flexible support can comprise indentations, additions of one or more materials, reliefs, and/or any other structure for modifying the vibrations of the flexible support and thus the haptic feeling.

### Arrangement of the Tactile Elements

The rigid tactile elements can be distributed over the support in various ways, notably as a function of the application, while following a spacing according to the invention.

The spacing between two adjacent rigid tactile elements can be selected as a function of the flexibility of the flexible support and of its thickness, so as to obtain the desired vibration amplitude for the flexible support and the desired location for the vibrations in the event of a multi-point tactile effect, while preserving the flexibility of the assembly.

The softer and/or the thinner the flexible support, the closer the elements can be brought together, while preserving a vibration amplitude for the flexible support that is sufficient to be tactilely detectable.

Preferably, the spacing between two adjacent rigid tactile elements (measured edge-to-edge) is greater than 10 mm. This minimum distance of 10 mm must be large enough to allow good flexibility to be provided for the flexible support, despite using a material for the flexible support that has the required rigidity.

Preferably, the spacing between two adjacent elements (measured edge-to-edge) is less than 100 mm, better still less than 50 mm, even better still less than 20 mm. This spacing is selected so that the vibration amplitude does not attenuate further between two rigid tactile elements.

At least some of the rigid tactile elements can be arranged in rows and/or in columns, notably on the same plane when the flexible support is laid flat, preferably in accordance with a regular array.

As a variant, the rigid tactile elements are arranged in a concentric distribution, or the like.

### Actuators

Each rigid tactile element can be provided with at least one actuator, for example, on the face thereof that is located on the side of the flexible support and/or on the opposite face thereof, preferably the face opposite the flexible support.

Each actuator can be disposed on a vibration antinode of the associated rigid tactile element.

Each actuator can be of the piezoelectric, ferroelectric, electromagnetic or thermal type, preferably of the piezoelectric type. In particular, each actuator can be piezoelectric ceramic, for example, PZT piezoelectric ceramic, or AIN piezoelectric.

The actuators can be in the form of a thin layer, for example, in the form of a thin layer of PZT.

Preferably, the shape and the arrangement of the actuators are selected so as to obtain the one or more desired vibration modes on the rigid tactile element.

The one or more actuators associated with a rigid tactile element can each assume an elongated shape, preferably along the width of the rigid tactile element it is in contact with in the case whereby the latter assumes a rectangular shape.

The one or more actuators can be disposed on either side of a median plane of the rigid tactile element. The one or more actuators can be in the vicinity of vibration nodes or antinodes.

The actuators can assume various shapes; they each have, for example, a general polygonal shape, notably a rectangular or square shape, or even a circular or annular shape.

It is also possible to combine several forms of actuators on the same rigid tactile element in order to be able to generate several different vibration modes, for example, alternatively, which allows diverse haptic effects to be obtained.

### Ancillary Systems

The interface can comprise a system for detecting a contact of the user on the touch surface, notably a capacitive detection structure, which is, as applicable, integrated into the haptic structure. As a variant, the system for detecting a contact of the user on the touch surface is an impedance tracking or voltage tracking structure.

The interface can comprise a system for at least partially superimposing an image on the touch surface. The interface thus can comprise a screen, preferably a screen integrating the haptic structure. The screen can notably comprise OLED-type pixels.

The interface can comprise at least one actuator for selectively shaping the interface according to at least two distinct shapes. This can be useful, for example, for changing the shape of the interface as a function of the tactile sensation to be reproduced, in order to improve the quality of the simulation, for example.

A further aim of the invention is a clothing article equipped with a haptic interface according to the invention, as defined above.

A further aim of the invention is a mobile device equipped with a haptic interface according to the invention, as defined above.

As a variant, the haptic interface according to the invention is integrated into a fabric, a bracelet, a display stand or any other curved surface.

In particular, the haptic interface according to the invention can be integrated into a dashboard. Indeed, the haptic effects created by the interface allow interaction with the dashboard by touching it, without having to look at it.

The haptic interface can be used for braille surfaces.

The interface can comprise ancillary vibrating means, for example, a small local vibrator, or fluid technology enabling vibration.

### Method for Generating a Haptic Effect

A further aim of the invention is a method for generating a haptic effect, notably a multi-point haptic effect, with a flexible haptic interface according to the invention, as defined above, in which method at least one rigid tactile element is mechanically excited by means of one or more actuators superimposed on this rigid tactile element, in order to vibrate the flexible support with a tactilely detectable vibration amplitude.

The features of the flexible haptic interface described above apply to the method in combination or independently of one another.

The method according to the invention can comprise the prior detection of the one or more positions of the one or more contacts of a user on the haptic interface by means of a detection system, then the modulation, by means of a control circuit, of the signals sent to the one or more actuators as a function of the one or more detected positions in order to mechanically induce a vibration of the rigid tactile elements and of the flexible support and to generate a haptic sensation on the touch surface.

It is thus possible to generate the desired haptic effect in the detected contact area.

The method can comprise the selective excitation of a single actuator or of only some of the actuators, according to a predefined excitation pattern; the excitation can occur so as to excite a given actuator without exciting any of the closest actuators, or without exciting any of the actuators surrounding the actuator that is excited; the excitation can also occur by exciting several actuators aligned with one another, without exciting the closest actuators located on the same side of the row connecting the excited actuators or on either side of this row. Other excitation patterns for the actuators are possible, depending on the desired result.

### Excitation of the Rigid Tactile Elements

The invention is not limited to a particular mechanical excitation of the rigid tactile elements. However, some types of excitation, and in particular some vibration modes of the tactile elements, facilitate the vibration of the flexible support and allow haptic effects to be generated in a relatively reliable manner.

Thus, the rigid tactile elements can be mechanically excited according to a first vibration mode called “flexural vibration mode”.

As a variant, the rigid tactile elements can be mechanically excited according to an antisymmetric Lamb mode.

The rigid tactile elements are mechanically excited at a frequency preferably ranging between 20 and 250 kHz, better still between 20 and 100 kHz, notably in order to vibrate each rigid tactile element at a mechanical resonance frequency.

The rigid tactile elements are preferably selected so as to resonate at a frequency ω that is greater than or equal to 20 kHz. The resonant frequency ω of the rigid tactile elements can be defined by the following formula:

$$ω = β \sqrt{\frac{{E}_{rigid} {h}_{rigid}^{3}}{{ρ}_{rigid} {a}_{rigid}^{4} ( 1 - {v}_{rigid}^{2} )}} ,$$

with ρ_{rigid} being the density of the rigid tactile elements, h_{rigid} being the thickness of the rigid tactile elements, E_{rigid} being the Young's modulus of the rigid tactile elements, a_{rigid} being the characteristic dimension of a rigid tactile element, v_{rigid} being the Poisson's ratio of the rigid tactile elements and β being a characteristic coefficient of the shape of the rigid tactile element, various examples of which are provided in the book by Harris entitled, “Shock and Vibration Handbook”.

The flexible support is selected so that the acoustic wave propagating on its surface is tactilely detectable by a user, i.e., so that the wavelength λ of the acoustic wave propagating on the surface is preferably greater than 2 mm. The wavelength λ can be defined by the following formula:

$$λ = 2 {π ( \frac{D}{{ρ}_{flexiblesupport} {h}_{flexiblesupport} {ω}^{2}} )}^{\frac{1}{4}} ,$$

with ρ_{flexiblesupport} being the density of the flexible support, h_{flexiblesupport} being the thickness of the flexible support, ω being the vibration frequency of the rigid tactile elements defined above, and D being the flexural rigidity of the flexible support, such that

$$D = \frac{{E}_{flexiblesupport} {h}_{flexiblesupport}^{3}}{12 ( 1 - {v}_{flexiblesupport}^{2} )} ,$$

with E_{flexiblesupport} being the Young's modulus of the flexible support and h_{flexiblesupport} being the thickness of the flexible support.

The signals sent to the actuators can be modulated at a frequency of less than 1,000 Hz, notably in order to modulate the friction. This modulation of the signals sent to the actuators notably allows ultrasonic lubrication. The term “ultrasonic lubrication” is understood to mean the reduction in friction due to the squeeze-film effect and to the intermittent contact when a finger passes over the surface, for example. This can allow the haptic feeling to be improved.

At least one actuator of a rigid tactile element located in the vicinity of an excited rigid tactile element may not be electrically powered.

Throughout the remainder of this document, the assembly made up of an actuator, of an associated rigid tactile element and of a portion of the flexible support superimposing the rigid tactile element is called a haptic resonator.

The assembly made up of a rigid tactile element, of one or more non-electrically powered actuators, and of a portion of the flexible support superimposing these elements, is called passive haptic resonator, as opposed to the active haptic resonator.

An active haptic resonator can allow ultrasonic vibration of the flexible support in a specific mode, which allows ultrasonic lubrication.

A passive haptic resonator can allow any ultrasonic waves generated by one or more neighboring active haptic resonators to be reflected and/or guided and/or can allow a barrier to be formed to the ultrasonic waves generated by one or more neighboring active haptic resonators.

It is possible to excite an actuator of a given first rigid tactile element, without exciting all the actuators of the rigid tactile elements surrounding this first rigid tactile element. The passive haptic resonators in the vicinity of an active haptic resonator can be considered to be acoustic mirrors. Indeed, they can reflect the ultrasonic waves emitted by one or more neighboring active haptic resonators, due to the difference in acoustic impedance.

The acoustic waveguides and/or mirrors created by the passive haptic resonators allow the ultrasonic waves emitted by the active haptic resonators to be contained and/or amplified, and allow a good location to be obtained for the ultrasonic vibrations in the vicinity of the active haptic resonators. This also allows the flexible haptic interface to be used to create multi-point haptic effects. Due to the location of the vibrations generated by the resonators, any feelings can be located.

At least two active resonators can be excited with different signals, notably with signals with modulations at different frequencies and/or amplitudes, so as to create a multi-point haptic effect. This can allow different feelings to be obtained on the touch surface.

Preferably, the reflection coefficient by a passive haptic resonator for the ultrasonic waves emitted by an active haptic resonator is greater than 50%, better still greater than 70%, more preferably greater than 90%.

The term “reflection coefficient by a passive haptic resonator for the ultrasonic waves emitted by an active haptic resonator” is understood to mean the value of R provided by the following formula:

$$R = \frac{{Z}_{flexiblesupport} - {Z}_{act . + rigid + flexible}}{{Z}_{flexiblesupport} + {Z}_{act . + rigid + flexible}} ,$$

with Z_{flexiblesupport} being the acoustic impedance of the flexible support and Z_{act.+rigid+flexible}, being the acoustic impedance of the assembly made up of an actuator, a rigid tactile element and the flexible support in contact with the rigid tactile element, with this latter impedance being substantially equal to the acoustic impedance of a rigid tactile element Z_{rigid}, where Z_{flexiblesupport}=ρ_{flexiblesupport}×c_{flexiblesupport}, with ρ_{flexiblesupport} being the density of the flexible support and c_{flexiblesupport} being the speed of the acoustic wave in the flexible support, and
Z_{rigid}=ρ_{rigid}×c_{rigid}, with ρ_{rigid} being the density of the rigid tactile element and c_{rigid} being the speed of the acoustic wave in the rigid tactile element,
with

$$c = \sqrt{\frac{E}{2 ρ ( 1 + v )}}$$

being the speed of an acoustic wave in a material with a Young's modulus E, a density ρ and a Poisson's ratio ν.

### Production

A further aim of the invention is a method for producing a haptic interface as defined above, comprising the following steps of:
(a) manufacturing an assembly comprising actuators and rigid tactile elements;
(b) producing the haptic interface with said assembly.

Step (a) can comprise:
(a1) producing a lower electrode by depositing, preferably by photolithography or by screen printing, at least a first layer of a conductive material onto the upper face of a rigid support, preferably a glass or silicon support;
(a2) depositing a conductive adhesive onto the lower electrode;
(a3) installing the actuators, preferably piezoelectric actuators, on the first layer thus formed by the lower electrode and the conductive adhesive, so as to establish a first electrical connection with the actuators;
(a4) depositing a layer of an insulator onto the previously deposited layers, for insulating the lower electrode;
(a5) thinning the insulating layer, for example, by chemical or laser etching, by abrasion, by compression, or by dissolution, in order to expose the upper surface of each actuator;
(a6) producing an upper electrode by depositing, preferably by evaporation or by screen printing, a layer of a conductive material onto the actuators thus exposed, so as to establish a second electrical connection with the actuators;
(a7) cutting or etching the rigid support, for example, into a square or a rectangular support, so as to obtain tactile elements each provided with one or more actuators.

The method of step (a) notably allows a plurality of tactile elements to be simply manufactured from the same support, for example, a glass plate.

As a variant, steps (a2) and (a3) can be replaced by a step corresponding to depositing a thin layer of lead zirconate titanate (PZT) onto the lower electrode, using a conventional thin layer deposition technique, notably by vacuum evaporation.

The actuator/rigid tactile element assemblies obtained in step (a) then can be applied to a flexible support in order to form a haptic interface according to the invention.

Step (b) thus can comprise:
(b1) depositing, notably by laminating, a separation film, notably a thermal film, onto a manufacturing support;
(b2) depositing, notably by laminating, a layer of flexible material, preferably made of polymer, onto the separation film;
(b3) depositing, notably by screen printing, electrical tracks onto the layer of flexible material;
(b4) depositing, notably by screen printing, a conductive adhesive onto the layer of flexible material;
(b5) installing previously produced tactile elements, provided with one or more actuators, on the layer of conductive adhesive thus deposited, with the actuators being disposed on the outer face of the tactile elements;
(b6) electrically connecting each lower electrode to the electrical tracks, preferably by masking and spraying a conductive material;
(b7) releasing the haptic interface from the manufacturing support, notably by heating the separation film, when said film is a thermal film, with this also allowing the manufacturing support to be recycled and/or recovered;
(b8) cutting the haptic interface according to the desired design.

Step (b) can further comprise an additional step, notably between steps (b6) and (b7), corresponding to the addition of a passivation layer, notably an insulating varnish, in order to electrically insulate the lower part of the haptic interface, with the lower part of the haptic interface corresponding to the surface comprising the rigid tactile elements and the actuators, opposite the touch surface.

The conductive adhesive used in step (a) and/or in step (b) can be an epoxy adhesive.

### BRIEF DESCRIPTION OF THE DRAWINGS

The invention will be better understood upon reading the following detailed description of non-limiting embodiments thereof, and with reference to the appended drawings, in which:

FIG. 1A is a schematic and partial longitudinal cross-section view of an example of a haptic interface according to the invention;

FIG. 1B is a partial and schematic top view of the haptic interface of FIG. 1A;

FIG. 2A is a perspective view of the haptic interface of FIG. 1B;

FIG. 2B is a bottom view of the haptic interface of FIG. 2A;

FIG. 3A is a simulation of the displacement field of an active haptic resonator without (on the left) and with (on the right) neighboring passive haptic resonators, on a regular array of nine resonators, as on the haptic interface of FIGS. 1A to 2B;

FIG. 3B and FIG. 3C are laser vibrometer measurements of the displacement field of the interface of FIG. 1B with a central active haptic resonator and neighboring passive haptic resonators;

FIG. 4 is an experimental measurement of the vibration amplitude of an active haptic resonator with a neighboring passive haptic resonator;

FIG. 5 is a simulation of the displacement field of the haptic interface of FIG. 1B with multi-point haptic effects;

FIG. 6 is an experimental measurement of the displacement field of the haptic interface of FIG. 1B with multi-point haptic effects;

FIG. 7 is an experimental measurement of the displacement field of the haptic interface of FIG. 1B with other multi-point haptic effects;

FIG. 8 is an experimental measurement of the displacement field of the haptic interface of FIG. 1B with other multi-point haptic effects;

FIG. 9A and FIG. 9B illustrate vibration modes of a rigid tactile element according to the invention;

FIG. 10A, FIG. 10B and FIG. 10C represent steps of an example of a method for producing a flexible haptic interface according to the invention.

### DETAILED DESCRIPTION

In the drawings, the actual proportions have not always been followed for the sake of clarity.

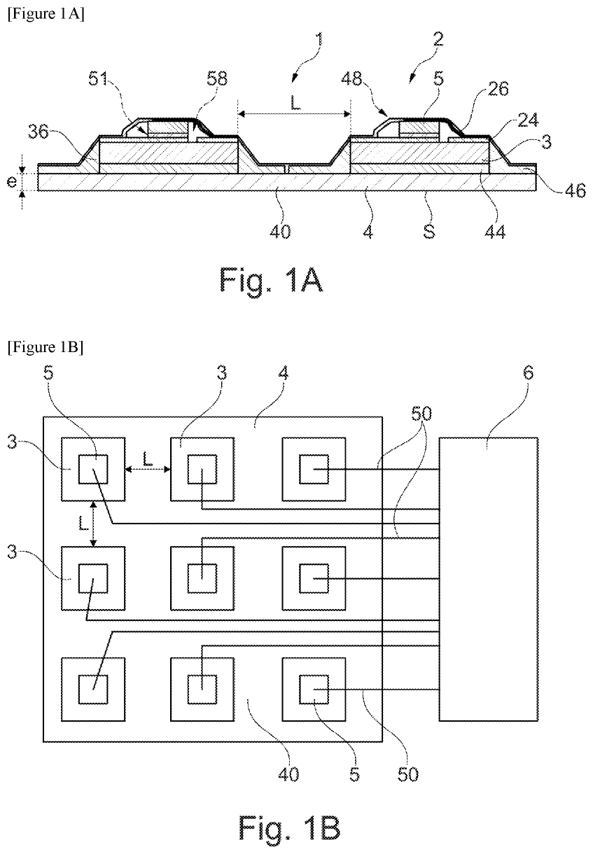

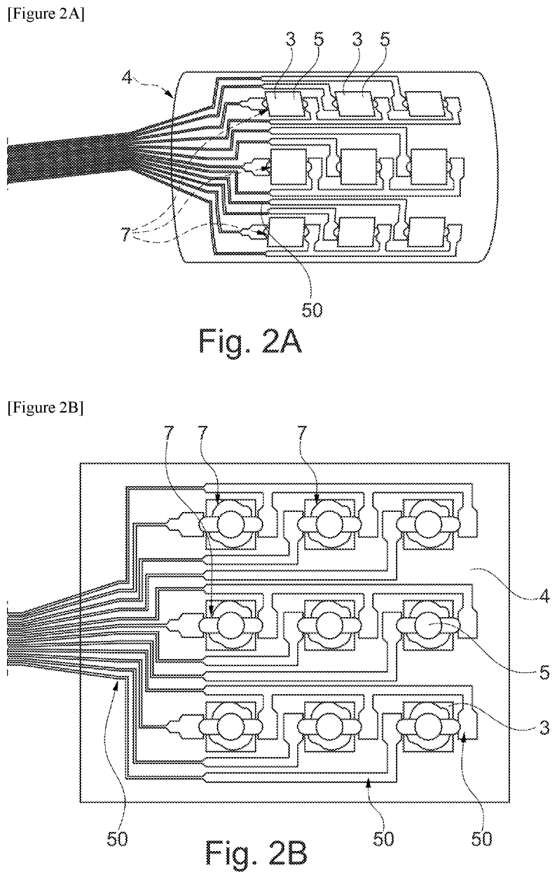

FIGS. 1A to 2B illustrate an example of a flexible haptic interface 1 according to the invention. The interface 1 comprises a haptic structure 2 defining a touch surface S able to be touched by a user and on which a haptic effect can be generated.

The haptic structure 2 comprises rigid tactile elements 3, only two of which are shown in FIG. 1A, supported by a flexible support 4. The rigid tactile elements 3 are, for example, made of glass, notably borosilicate glass, or silicon. The rigid tactile elements 3 are attached, for example, to the flexible support 4 by virtue of a layer of conductive adhesive 46, notably a layer of epoxy adhesive.

Throughout the description, including the claims, the term “in contact” should be understood to mean including the possible presence of a thin layer of adhesive used to assemble the adjacent parts. Thus, the rigid elements 3 and the flexible support 4 are considered to be in contact.

The flexible support 4 forms hinges 40 extending between the tactile elements 3.

In the considered example, each tactile element 3 is provided with a single actuator 5, preferably a piezoelectric actuator, for example, made of lead zirconate titanate (PZT), with said actuator being attached, for example, to the rigid tactile element 3 by means of a layer of adhesive 51, notably epoxy. The actuator 5 is connected to a control circuit 6, shown in FIG. 1B, by means of electrical connections 50. The electrical connection between the actuator 5 and the control circuit 6 is notably enabled by virtue of layers 26, 24, 36 and 46 of electrically conductive materials. Furthermore, a layer 58 of an electrically insulating material allows the electrodes of the actuator 5 to be electrically insulated.

The actuators also can be covered on the side opposite the support 4 with a layer 48 of a protective material.

The control circuit 6 is configured to modulate the signals sent to each of the actuators 5 in order to mechanically induce vibrations thereon and to selectively mechanically excite one or more rigid tactile elements 3.

The excitation of a rigid tactile element 3 causes the flexible support 4 to vibrate locally.

The arrangement of the tactile elements 3 on the flexible support 4, and in particular the spacing L between two adjacent rigid tactile elements 3, is selected so that when the tactile elements 3 are excited mechanically by means of the actuators 5, the vibration amplitude of the resulting flexible support is tactilely detectable.

The spacing Z between two rigid tactile elements 3 is also selected so that the haptic interface allows localized haptic effects to be generated, and optionally multi-point haptic effects. The ratio e/L thus satisfies the relationship e/L<0.02, where e denotes the thickness of the flexible support.

The haptic structure 2 can assume any shape and diverse sizes. Its dimensions are, for example, depending on the application, of the order of cms, dms or meters.

The rigid tactile elements 3 can assume diverse shapes, as a front view, for example, rectangular, square, circular or other shapes. Their largest dimension ranges, for example, between a few hundred microns to a few centimeters on the side, preferably from 2 mm to 1 cm on the side.

The rigid tactile elements 3 can be distributed over the support 4 in various configurations.

For example, as illustrated in FIG. 1B, the elements 3 are distributed over the support 4 in three rows and three columns, as a regular array.

In other embodiments (not illustrated), the interface 1 comprises rigid tactile elements 3 of different sizes and/or shapes, or even rigid tactile elements 3 disposed in a concentric or staggered distribution.

Notably, the size of the rigid tactile elements 3 can be adjusted so as to generate haptic effects tactilely simulating greater or lesser patterns.

The rigid tactile elements 3 are disposed on the support 4 so that the haptic structure 2 retains overall flexibility in at least one direction, and better still in all directions.

However, as mentioned above, this arrangement is subject to certain constraints in order to obtain an effect that is tactilely perceptible by the user. A vibration of the flexible support or of the tactile elements is considered to be tactilely perceptible when its amplitude typically exceeds 1 micron under a load ranging between 0.05 and 0.5 N.

The vibration amplitude of a rigid tactile element 3 depends, among other things, on its dimensions, its rigidity and the vibration mode in which it is activated.

The vibration amplitude of the flexible support depends on its thickness e, on the features of the one or more materials forming the flexible support 4, and on the spacing L between two rigid tactile elements 3.

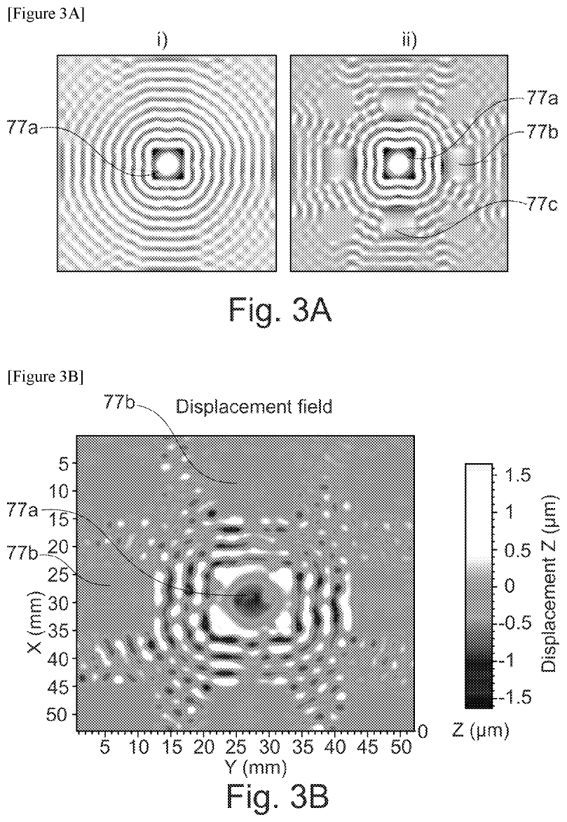

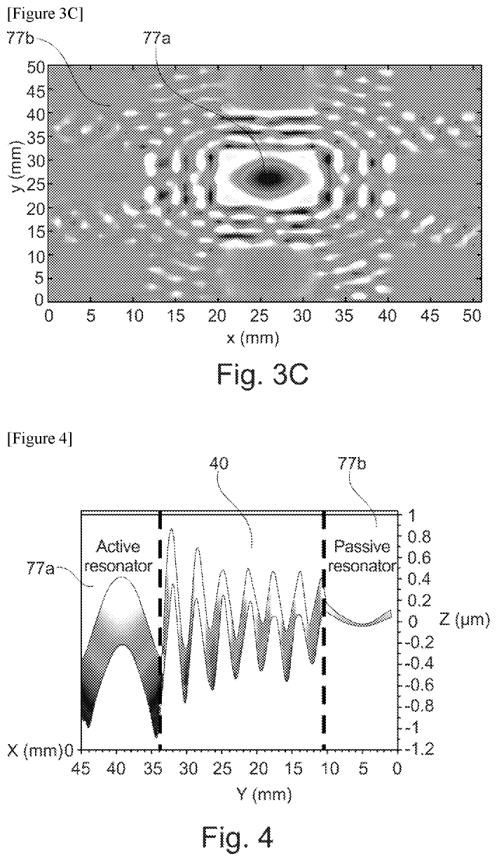

FIG. 3A i) illustrates a digital simulation, on the COMSOL commercial software, of a central active haptic resonator 77a surrounded by a wide range of flexible supports without other haptic resonators.

In comparison, FIG. 3A ii) illustrates a digital simulation, on the COMSOL commercial software, of the same active haptic resonator 77a in a regular array of nine haptic resonators such as that of the interface of FIGS. 1A to 2B, with the active haptic resonator 77a being the central resonator of the array and the eight other haptic resonators being passive haptic resonators 77b. This figure shows the effect of the acoustic mirror, as well as the waveguide created by the passive haptic resonators 77b.

FIGS. 3B and 3C illustrate two experimental validations on the laser vibrometer, from the observations of FIG. 2A ii). A central localized friction zone, corresponding to the active haptic resonator 77a, still can be identified, with the waves being contained in the vicinity of this resonator by means of the eight passive haptic resonators 77b.

FIG. 4 illustrates a similar experimental validation, comprising a single passive haptic resonator 77b adjacent to an active haptic resonator 77a. The attenuation of the acoustic wave in the vicinity of the hinge 40 between the two resonators 77a and 77b can be clearly seen. This is an attenuation of the exp(−α×r) type, with r being the distance to the active haptic resonator and α being the damping coefficient of the amplitude of the wave, where

$$α = \frac{variation of the amplitude of the wave}{distance} .$$

The spacing L between the rigid tactile elements 3 is notably determined as a function of the damping coefficient α, or of the quality factor

$$Q = \frac{1}{2 α}$$

of a resonator (namely, a haptic resonator that can be considered to be a harmonic oscillator), since the intention is to avoid having complete attenuation of the wave between two haptic resonators.

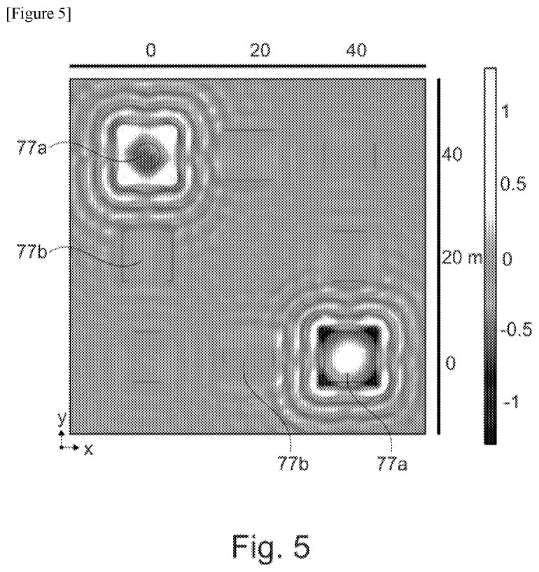

FIG. 5 illustrates a simulation, using the COMSOL software, of a multi-point haptic effect on the haptic interface with nine rigid tactile elements arranged as a regular array excited at a frequency of 30.2 kHz; two localized friction zones can be seen in the vicinity of two active haptic resonators 77a, while the seven other haptic resonators 77b are passive.

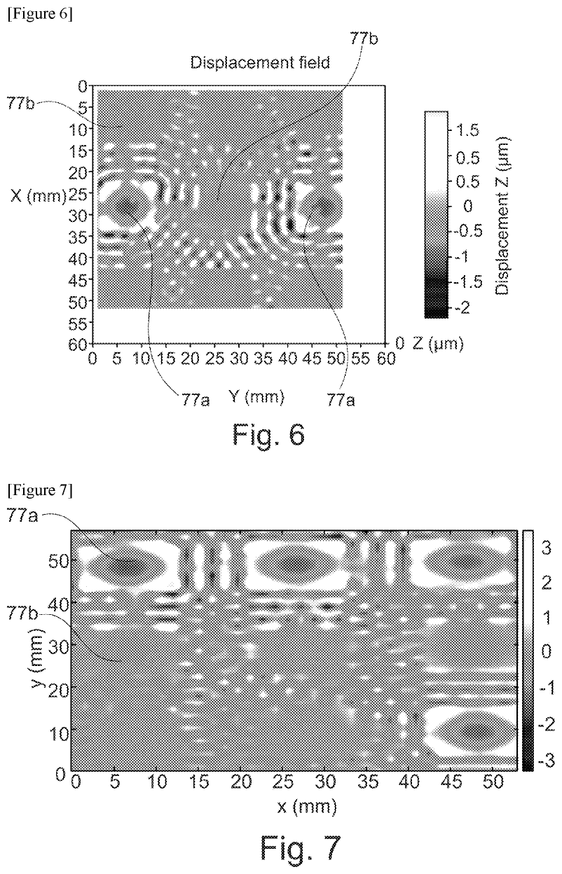

FIG. 6 illustrates the experimental results obtained with two active haptic resonators 77a and seven passive haptic resonators 77b. The friction zones located in the vicinity of the resonators 77a are clearly identifiable.

By virtue of the control circuit 6, it is possible for the signals sent to the actuators 5 of the two active haptic resonators 77a to be modulated differently in order to mechanically excite the resonators 77a differently. For example, the first active haptic resonator 77a can be modulated at 50 Hz in order to feel major vibrations, and the second active haptic resonator 77a can be modulated at 250 Hz in order to feel minor vibrations.

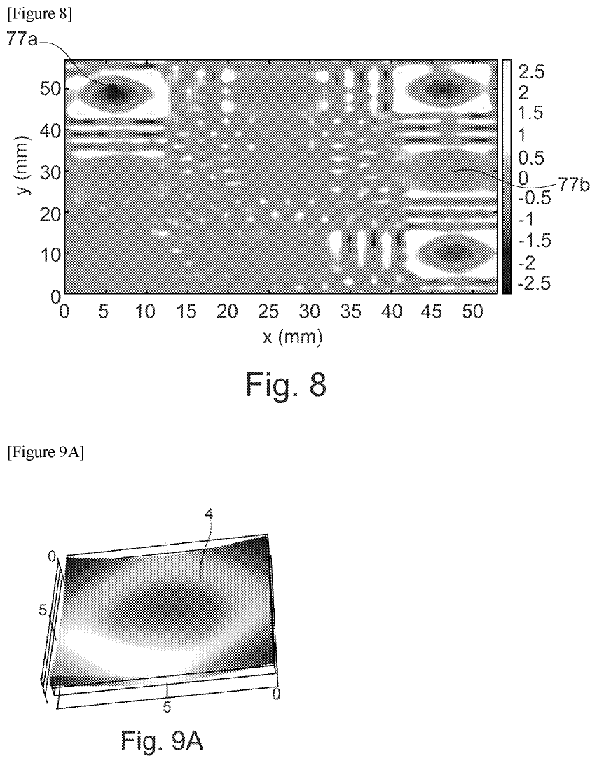

FIGS. 7 and 8 illustrate experimental results obtained for excitation patterns where some resonators are active while the others are passive.

FIG. 7 identifies three active resonators 77a on the upper row, as well as an active resonator 77a on the bottom right-hand side. The vibration amplitude in the vicinity of these resonators is significant, unlike that which can be observed in the vicinity of the five passive resonators 77b.

FIG. 8 identifies three active resonators 77a, respectively on the top left-hand side, on the top right-hand side and on the bottom right-hand side. The vibration amplitude in the vicinity of these resonators is significant, unlike that which can be observed in the vicinity of the six passive resonators 77b.

These observations confirm that the passive haptic resonators 77b act as acoustic mirrors in order to locate the vibrations in the vicinity of the active haptic resonators 77a.

By virtue of the actuators 5, the tactile elements 3 can be vibrated according to vibration modes that are adapted for generating the haptic effects that are intended for them.

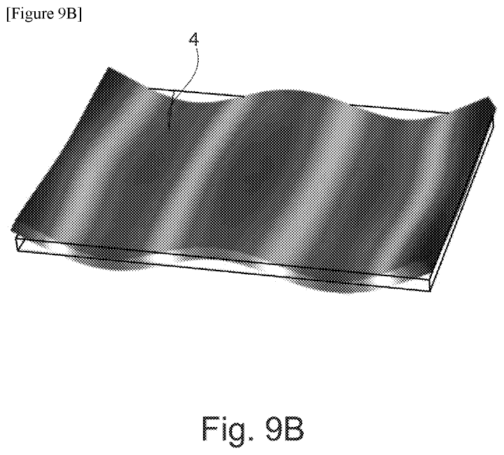

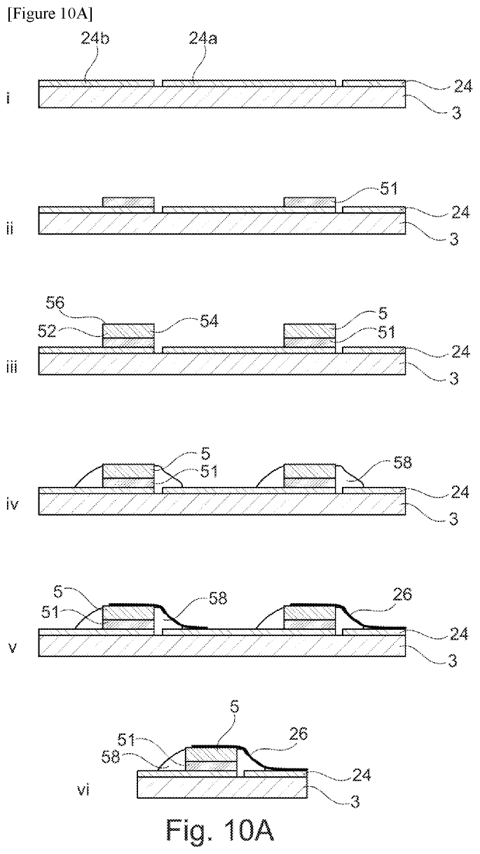

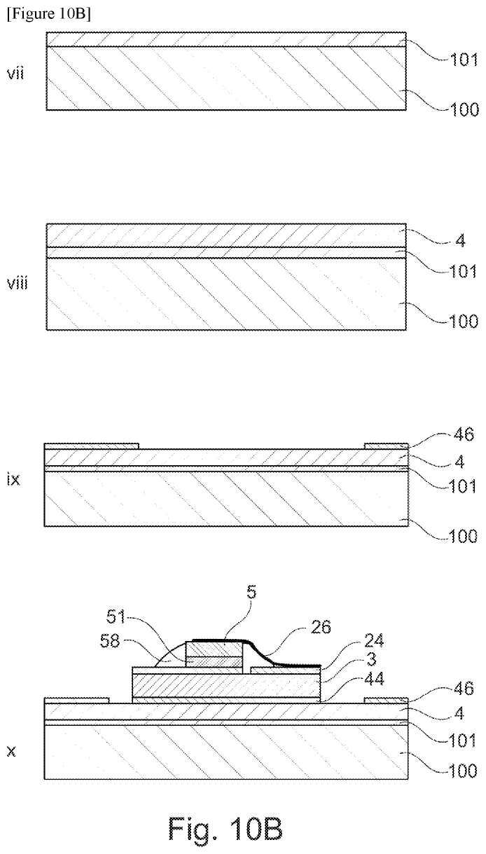

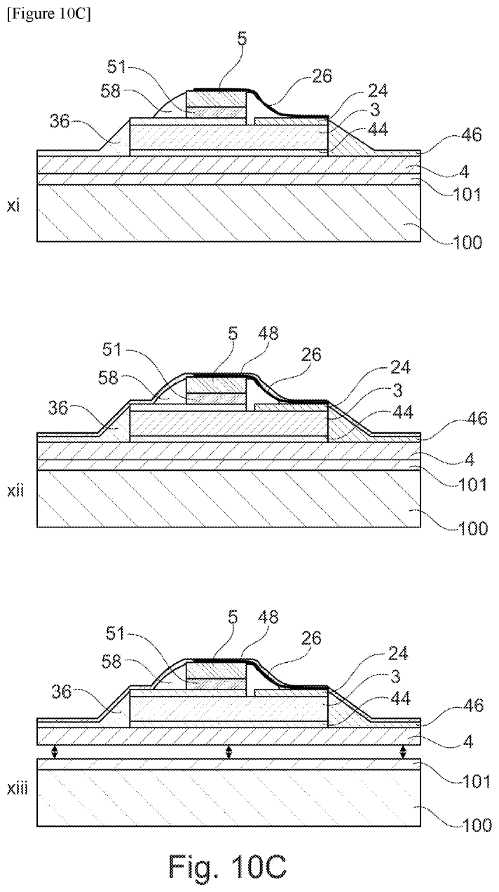

Preferably, rectangular actuators are used in order to obtain a Lamb mode, illustrated in FIG. 9B, and square and/or circular actuators are used in order to obtain an off-plan mode, such as the flexural mode, illustrated in FIG. 9A.

The flexible haptic interface 1 described above can be produced using the method comprising the steps illustrated in FIGS. 11A to 11C, and described hereafter.

In step i, a first layer 24 of an electrically conductive material, for example, gold, is deposited onto the upper face of a rigid plate (precursor of the elements 3), notably a glass or silicon plate, with the thickness of the rigid plate being, for example, substantially equal to 500 μm.

The layer 24 is, for example, gold deposited by photolithography or by screen printing. As a variant, the layer 24 is silver ink deposited by screen printing, for example, over a thickness ranging between 5 and 12 μm.

The layer 24 is discontinuous: it comprises, for example, several separate sections 24a and 24b, which form the electrical power supply tracks of the actuators 5 that will contact the tactile element 3.

The thickness of the layer 24 is 300 nm, for example.

In step ii, a conductive adhesive 51, for example, an epoxy adhesive, is deposited onto the layer 24, for example, over a thickness of 30 μm.

In step iii, actuators 5 comprising, for example, a lower electrode 52, a piezoelectric or ferroelectric layer 54 and an upper electrode 56 are installed. As a variant, the actuators 5 comprise only the layer 54.

The lower electrode 52 of the actuators 5 is then connected to the track 24 by virtue of the layer of conductive adhesive 51. The deformation of the layer 54 under the effect of a potential difference applied between the electrodes is transferred to the element 3 by a unimorphic effect in the layer 51.

The layer 54 is, for example, of the lead zirconate titanate (PZT) type. It also can be made of aluminum nitride (AIN), zinc oxide (ZnO) or any other suitable piezoelectric or ferroelectric material. The layer 54 also can be thinned and adjusted to the desired thickness.

Notably, a commercial piezoelectric ceramic can be used for the actuator 5, or the actuator 5 can be formed by depositing thin layers and shaping on the rigid precursor plate of the elements 3, as described in patent FR 3082997.

In step iv, each actuator 5 is then covered with an electrical insulation layer 58, for example, made of a polymer material, in order to retain the actuator 5 and to isolate the electrodes 52 and 56. Only part of the power supply track 24 remains uncovered.

The insulating layer 58 is then thinned from above in order to reveal the electrode 56, with a view to depositing, in step v, a layer of conductive material 26 connecting the upper electrode 56 with the supply track 24.

The layer 26 is notably a deposit of titanium that is 20 nm or 500 nm thick, for example, obtained by evaporation. As a variant, the layer 26 is silver ink obtained by screen printing that is 5 to 12 microns thick, for example.

The rigid precursor plate of the elements 3 then can be thinned on the rear face, notably by rectification, for example, to a thickness of 400 microns.

Finally, the plate can be cut out, in step vi, in order to obtain rigid tactile elements 3 assuming the desired size, squares or rectangles, for example, and provided with the anticipated number of actuators 5.

The rigid tactile elements 3 thus obtained and provided with their actuators 5 subsequently can be transferred and attached on a flexible substrate 4 in order to form a haptic structure 2, for example, according to the production steps described hereafter. In particular, a haptic structure 2 such as that described above can be obtained according to the following steps.

In step vii, a thermal film 101 is laminated, for example, an adhesive tape that adheres strongly at ambient temperature and can be easily removed by heating, notably at 170 °C, on a manufacturing substrate, notably a silicon wafer 100.

In step viii, a flexible layer 4 is formed on the thermal film 101, for example, a layer of KAPTON or PEEK, notably by lamination. The flexible layer 4 must be able to withstand the temperature at which the thermal film 101 disaggregates, notably 170 °C.

Next, a layer of an electrically conductive material 46, for example, silver ink deposited by screen printing over a thickness ranging between 5 and 12 microns, is deposited in step ix in order to form the electrical connection between each actuator 5 and the control circuit 6.

The layer 46 is discontinuous: it comprises several separate sections that form the electrical power supply tracks of the actuators 5 that will contact the tactile elements 3.

In step x, the rigid tactile elements 3 are then installed at the desired locations on the flexible layer 4. The tactile elements 3 are retained, for example, by virtue of a layer 44 of rigid adhesive, for example, of the epoxy type, deposited onto the layer 24, for example, by screen printing.

A layer 36 of conductive material, for example, silver ink, is deposited in step xi, allowing the electrical contact to be resumed between the upper electrode 56 and the layer 46.

It is then possible to continuously cover, in step xii, for example, by rolling or bonding, all the tactile elements 3 and their actuators 5 with a layer 48, notably a film of soft polymer or a varnish, in order to protect the assembly on the face thereof opposite the touch surface.

Finally, in step xiii, the manufacturing substrate 100 is removed by heating the assembly at least to the temperature at which the thermal film disaggregates, in order to expose the flexible layer 4, with the exposed surface defining the touch surface S of the flexible haptic interface 1.

The flexible haptic interface 1 thus obtained can be cut into several interfaces as required.

The interface according to the invention can also comprise a detection system (not shown), for example, a capacitive system known in the prior art, for detecting at least one point of contact of the finger of the user with the surface S.

The interface 1 can further comprise one or more ancillary devices for improving the user experience, notably in order to provide a multi-sensory experience.

The interface 1 can thus comprise a flexible screen (not shown) that allows an image to be superimposed on the touch surface S and, for example, gives the user the impression of virtually touching what they observe on the screen. The interface 1 can also comprise one or more loudspeakers (not shown) in order to add a sound effect.

The tactile elements 3 of the same group can be activated using an identical vibration mode for all the tactile elements of the group, or specific to each tactile element, depending on the desired effect.

The interface 1 according to the invention can be integrated into a clothing item. As a variant, it can be integrated into a mobile device, for example, a flexible telephone.

The haptic structure 2 can also, in other examples, change shape depending on the desired haptic effect, with the interface 1 being able, given its flexibility, to be a reconfigurable tangible object.

1. A flexible haptic interface defining a touch surface capable of being touched by at least one user, the interface comprising:
a plurality of rigid tactile elements connected by a flexible support; and
at least one actuator, superimposed on each rigid tactile element, with the actuators being arranged to transfer mechanical excitation to the rigid tactile elements in order to vibrate the flexible support,
with the ratio e/L of a thickness e of the flexible support to a spacing L between at least two adjacent tactile elements being less than or equal to 0.02,
with a reflection coefficient R being greater than 50%, where
$$R = \frac{{Z}_{flexiblesupport} - {Z}_{act . + rigid + flexible}}{{Z}_{flexiblesupport} + {Z}_{act . + rigid + flexible}} ,$$
with Z_{flexiblesupport} being an acoustic impedance of the flexible support and Z_{act.+rigid+flexible} being an acoustic impedance of the assembly made up of an actuator, a rigid tactile element and the flexible support in contact with the rigid tactile element, with this latter impedance being substantially equal to an acoustic impedance of a rigid tactile element Z_{rigid}, where Z_{flexiblesupport}=ρ_{flexiblesupport}×c_{flexiblesupport}, with ρ_{flexiblesupport} being a density of the flexible support and c_{flexiblesupport} being a speed of an acoustic wave in the flexible support, and
Z_{rigid}=ρ_{rigid}×c_{rigid}, with ρ_{rigid} being a density of the rigid tactile element and c_{rigid} being a speed of an acoustic wave in the rigid tactile element,
with
$$c = \sqrt{\frac{E}{2 ρ ( 1 + v )}}$$
being a speed of an acoustic wave in a material with a Young's modulus E, a density ρ and a Poisson's ratio v.

2. The haptic interface as claimed in claim 1, wherein the flexible support has an equivalent Young's modulus E that is greater than or equal to 1.5 GPa.

3. The haptic interface as claimed in claim 1, wherein the flexible support is formed by a polymeric material.

4. The haptic interface as claimed in claim 1, wherein the flexible support has a substantially constant thickness e, with the thickness ranging between 25 and 200 microns.

5. The haptic interface as claimed in claim 1, wherein the spacing is greater than 10 mm.

6. The haptic interface as claimed in claim 1, wherein at least some of the rigid tactile elements assume a general polyhedral shape.

7. The haptic interface as claimed in claim 1, wherein at least two rigid tactile elements have rigid supports that are different from each other.

8. The haptic interface as claimed claim 1, wherein at least some of the rigid tactile elements are arranged in rows and/or in columns on the same plane when the interface is flat.

9. The haptic interface as claimed in claim 1, comprising a control circuit configured to modulate the signals sent to the actuators in order to mechanically induce a vibration of the rigid tactile elements and of the flexible support and to generate a haptic sensation on the touch surface, with the control circuit being configured so as to allow the modulation of each actuator to be individually controlled.

10. The haptic interface as claimed in claim 1, wherein each actuator is disposed on a vibration antinode of the associated rigid tactile element.

11. The haptic interface as claimed in claim 1, wherein the actuators are of the piezoelectric, ferroelectric, electromagnetic or thermal type.

12. A method for generating a haptic effect with a flexible haptic interface as claimed in claim 1, in which method at least one rigid tactile element is mechanically excited by means of one or more actuators superimposed on the one or more elements, in order to vibrate the flexible support with a tactilely detectable vibration amplitude.

13. The method as claimed in claim 12, wherein the rigid tactile elements are mechanically excited at a frequency ranging between 20 and 250 kHz, in order to vibrate each rigid tactile element at a mechanical resonance frequency.

14. The method as claimed in claim 12, wherein at least one actuator of a rigid tactile element located in the vicinity of an excited rigid tactile element is not electrically powered.

15. The method as claimed in claim 12, wherein an actuator of a given first rigid tactile element is excited, without exciting all the actuators of the rigid tactile elements surrounding this first tactile element.

16. The method as claimed in claim 12, wherein at least two active resonators are excited with different signals having modulations at different frequencies and/or amplitudes, so as to create a multi-point haptic effect.

17. A method for manufacturing a flexible haptic interface as claimed in claim 1, comprising:
producing a lower electrode by depositing at least a first layer of a conductive material onto the face of a upper rigid support;
depositing a conductive adhesive onto the lower electrode;
installing the actuators on the first layer formed by the lower electrode and the conductive adhesive, so as to establish a first electrical connection with the actuators;
depositing a layer of an insulator onto the previously deposited layers, for insulating the lower electrode;
thinning the insulating layer in order to expose the upper surface of each actuator;
producing an upper electrode by depositing a layer of a conductive material onto the actuators thus-exposed, so as to establish a second electrical connection with the actuators;
cutting the rigid square or rectangular support, so as to obtain rigid tactile elements each provided with one or more actuators;
depositing a separation film onto a manufacturing support;
depositing a layer of flexible material made of polymer, onto the separation film;
depositing electrical tracks onto the layer of flexible material;
depositing a conductive adhesive onto the layer of flexible material;
installing the rigid tactile elements produced in the step of cutting the rigid square or rectangular support, so as to obtain rigid tactile elements each provided with one or more actuators, provided with one or more actuators, on the layer of conductive adhesive deposited, with the actuators being disposed on the outer face of the tactile elements;
electrically connecting each lower electrode to the electrical tracks;
releasing the haptic interface from the manufacturing support, by heating the separation film, when said film is a thermal film;
cutting the haptic interface according to the desired design.
